(19) United States
(12) Patent Application Publication
(10) Pub. No.: US 2008/0274618 A1
(43) Pub. Date: Nov. 6, 2008

(54) POLISHING COMPOSITION AND METHOD FOR HIGH SELECTIVITY POLYSILICON CMP

(75) Inventor: Bradley Kraft, Fairport, NY (US)

Correspondence Address: RANKIN, HILL & CLARK LLP, 925 EUCLID AVENUE, SUITE 700, CLEVELAND, OH, 44115-1405, US

(73) Assignee: FERRO CORPORATION, Cleveland, OH (US)

(21) Appl. No.: 11/744,539

(22) Filed: May 4, 2007

(51) Int. Cl. H01L 21/304; C09K 13/00; C09K 13/06

(52) U.S. Cl. 438/693; 252/79.1; 252/79.2; 252/79.4

(57) ABSTRACT

The present invention provides a polishing composition and a method for removing polysilicon in preference to silicon dioxide, silicate glasses and/or silicon nitride via chemical-mechanical polishing during semiconductor device fabrication. In a preferred embodiment, the polishing composition includes an aqueous dispersion of ceria abrasive particles, from about 0.005% to about 0.15% by weight of a polyethyleneimine and a sufficient amount of an acid to adjust the pH of the polishing composition within the range of from about 4.7 to about 5.1. The polishing composition can be used to remove polysilicon via CMP at removal rates that are acceptable in semiconductor device fabrication applications while simultaneously suppressing the rate at which silicon dioxide, silicate glasses and silicon nitride are removed.

### BACKGROUND OF INVENTION

1. Field of Invention

The present invention relates to a polishing composition and a method for removing polysilicon in preference to silicon dioxide, silicate glasses and/or silicon nitride via chemical-mechanical polishing during semiconductor device fabrication.

2. Description of Related Art

Lee et al., U.S. Pat. No. 7,144,815 B2 (hereinafter referred to as the “Lee et al. patent”), discloses a chemical-mechanical polishing (“CMP”) composition that allows for control of removal rates of a silicon oxide layer and a silicon nitride layer exposed during polishing of a polysilicon layer during semiconductor device fabrication. The CMP composition described in the Lee et al. patent includes an abrasive, deionized water, a pH controlling agent (pH=11) and an additive that can reduce the removal rates of a silicon nitride layer and a silicon oxide layer. The Lee et al. patent teaches that the additive can be polyethyleneimine (“PEI”), which is preferably used in combination with a choline derivative such as choline chloride. All of the embodiments of the invention disclosed in the Lee et al. patent utilize fumed silica as the abrasive. The Lee et al. patent teaches that the PEI content of the CMP composition is preferably greater than 0.2% by weight of the entire CMP composition unless a choline derivative is also present, in which case the PEI content of the CMP composition can be less than 0.2% by weight of the entire CMP composition.

The CMP composition according to the Lee et al. patent is suitable for use in removing polysilicon in preference to silicon oxides and silicon nitride during semiconductor device fabrication. But a need exists for an improved polishing composition and method for high selectivity polysilicon CMP.

### BRIEF SUMMARY OF THE INVENTION

The present invention provides a polishing composition and a method for removing polysilicon in preference to silicon dioxide, silicate glasses and/or silicon nitride via chemical-mechanical polishing during semiconductor device fabrication. In a preferred embodiment, the polishing composition according to the invention consists essentially of an aqueous dispersion of ceria abrasive particles, from about 0.005% to about 0.15% by weight of a polyethyleneimine and a sufficient amount of an acid to adjust the pH of the polishing composition within the range of from about 4.7 to about 5.1. The polishing composition can be used to remove polysilicon via CMP at removal rates that are acceptable in semiconductor device fabrication applications while simultaneously suppressing the rate at which silicon dioxide, silicate glasses and silicon nitride are removed.

The foregoing and other features of the invention are hereinafter more fully described and particularly pointed out in the claims, the following description setting forth in detail certain illustrative embodiments of the invention, these being indicative, however, of but a few of the various ways in which the principles of the present invention may be employed.

### BRIEF DESCRIPTION OF THE DRAWINGS

FIG. 1 is a graph showing the removal rate of borophosphosilicate glass, silicon nitride and thermally grown silicon dioxide as a function of PEI concentration obtained through the use of three exemplary polishing compositions according to the present invention.

FIG. 2 is a graph showing the removal rate of polysilicon, silicon nitride and thermally grown silicon dioxide as a function of PEI concentration obtained through the use of a control CMP composition and three exemplary polishing compositions according to the present invention.

### DETAILED DESCRIPTION OF THE INVENTION

Silicon is a non-metallic element that is widely used in semiconductor device fabrication. Polysilicon, which is also known as polycrystalline silicon, consists of multiple small silicon crystals. Polysilicon is used, for example, as a conducting gate material in metal-oxide-semiconductor field-effect transistor (“MOSFET”) and in complementary metal-oxide-semiconductor (“CMOS”) processing technologies. It can be deposited using low-pressure chemical-vapour deposition (“LPCVD”) reactors at high temperatures and other processing techniques. In many instances, it is doped with elements having either 3 valence electrons (“P-doped”) or five valence electrons (“N-doped”) to increase the number of charge carriers. Throughout the instant specification and in the appended claims, the term “polysilicon” refers to deposits consisting essentially of small silicon crystals, whether doped or undoped.

The present invention provides a polishing composition and a method for removing polysilicon in preference to silicon dioxide, silicate glasses and/or silicon nitride via chemical-mechanical polishing during semiconductor device fabrication. Throughout the instant specification and in the appended claims, the term “silicon dioxide” refers to any deposit having predominantly the structure of SiO₂, which may have been deposited or formed by any means including, but not limited to, thermally grown silicon dioxide. The term “silicate glasses” refers to glasses containing silicon dioxide and other materials and includes, for example, materials such as borophosposilicate glass (“BPSG”), phosphorsilicate glass (“PSG”) and borosilicate glass (“BSG”).

Polishing compositions according to the invention comprise aqueous dispersions of abrasive particles, a polyalkyl amine compound and a sufficient amount of a pH adjusting material to adjust the pH of the polishing composition within the range of from about 3.5 to about 7, and most preferably within the range of from about 4.7 to about 5.1. Polishing compositions according to the invention preferably do not contain any choline derivatives such as choline chloride.

The abrasive particles used in the polishing composition according to the present invention perform the function of mechanical grinding. The preferred abrasive particles for use in the invention are formed of ceria. Silica and alumina abrasives cannot be used. Alumina simply does not remove polysilicon at an acceptable polishing rate. And silica can only be used to remove polysilicon at an acceptable polishing rate when the pH of the polishing composition is greater than 9. But at this pH, the silica abrasive particles are negatively charged and therefore interact with positively charged polyalky amine compounds to form large agglomerates, which results in the formation of an unstable polishing composition that can produce high defect counts on polished wafers. Although silica and alumina are unsuitable for use as abrasives in the invention, it may be possible to use other abrasive particles such as, for example, copper oxide, iron oxide, nickel oxide, manganese oxide, silicon carbide, silicon nitride, tin oxide, titania, titanium carbide, tungsten oxide, yttria, zirconia, and combinations thereof, provided such abrasives provide an acceptable polishing rate and do not interact with the polyaklyamines to form agglomerates.

The abrasive particles preferably have a mean diameter (secondary particle size) ranging from about 20 nm to about 1000 nm, with a maximum diameter of less than about 10,000 nm. If the mean diameter of the abrasive particles is very small, the polishing rate of the polishing composition can be unacceptably low. If the mean diameter of the abrasive particles is large, unacceptable scratching can occur on the surface of the article being polished. Optimally, the abrasive particles consist of ceria having a mean diameter within the range of from about 100 nm to less than 150 nm.

The abrasive particles can be dispersed in water as discrete particles before polishing to form a slurry, which is then disposed between a polishing pad and a surface of a workpiece. Alternatively, the abrasive particles can initially be bonded to the polishing pad, and the polishing composition can be formed in situ by dissociation of the abrasive particles from the polishing pad during polishing of the surface of the workpiece.

When dispersed to form an aqueous slurry prior to polishing, the abrasive particles are preferably present in the polishing composition in an amount of from about 0.1% to about 8% by weight of the polishing composition, more preferably from about 0.5% to about 4% by weight of the polishing composition, and most preferably from about 1.5% to about 2.5%, or about 2.0%, by weight of the polishing composition.

The polyalkyl amine compound(s) perform the function of suppressing the removal rate of silicon oxide, silicon nitride, and silicate glasses during polishing. The polyalkyl amine compounds used in the polishing composition according to the invention may comprise any one or a mixture of a variety of polyalkyl amines having a charge density greater than 7 meq/gram at a pH of 4.5. Charge density refers to the number of protonated amine groups at a specified pH. Polyethyleneimine (PEI) is presently the most preferred polyalkyl amine for use in the polishing composition according to the present invention, although it may be possible to use other compounds of sufficiently high charge density such as homopolymers and copolymers of polyvinylamine, polyaniline, polyvinylaniline, polyvinylpyridine. Preferably, PEI is present in an amount of from about 0.005% to about 0.15% by weight of the polishing composition, with the optimal range being from about 0.01% to about 0.1% by weight of the polishing composition.

The suppression of the removal rate of silicon dioxide, silicate glasses and silicon nitride films is relatively insensitive to the molecular weight of the PEI. PEI ranging between from about 800 to about 750,000 g/mol can be used in the invention. For processing ease, however, the preferred molecular weight of the PEI is between about 2,000 and about 70,000 g/mol.

Polishing compositions according to the present invention exhibit high selectivity of polysilicon to silicon dioxide, silicate glasses and silicon nitride over a pH range of about 3.5 to about 7. Preferably, however, the pH of the polishing composition is adjusted within the range of from about 4.0 to about 6.5 using a pH adjusting compound such as nitric acid. It will be appreciated that the pH of the polishing composition be adjusted by the addition of acids and/or bases. Nitric acid is the presently preferred acid for lowering the pH of the polishing composition, and potassium hydroxide and ammonium hydroxide are preferred bases for increasing the pH of the polishing composition. It will be appreciated that the selection of a pH adjuster is not critical, and that other acids and bases can be used in the practice of the invention. The polishing composition may also contain optional surfactants, pH buffers, anti-foaming agents, and dispersing agents, which are well known.

In the presently most preferred embodiment of the invention, the polishing composition consists essentially of an aqueous dispersion of ceria abrasive particles, from about 0.005% to about 0.15% by weight of a PEI and a sufficient amount of an acid to adjust the pH of the polishing composition within the range of from about 4.7 to about 5.1. The amount of ceria abrasive particles in the polishing composition is preferably within the range of from about 1.0% to about 3.0%, and most preferably about 2.0%, by weight of the polishing composition. The ceria abrasive particles preferably have a mean average particle diameter within the range of from about 100 to less than 150 nm, and are prepared by calcining a cerium carbonate precursor. The PEI preferably has a molecular weight in the range of 10,000 to 40,000 g/mol, and most preferably about 25,000 g/mol. Nitric acid is used to adjust the pH to between 4.9 and 5.0. The polishing composition does not contain any choline derivatives (i.e., it is “choline free”).

The polishing composition can be used to remove polysilicon via CMP at removal rates that are acceptable in semiconductor device fabrication applications while simultaneously suppressing the rate at which silicon dioxide, silicate glasses and silicon nitride are removed.

The present invention also provides a method of removing polysilicon in preference to silicon dioxide, silicate glasses and/or silicon nitride. The method comprises providing a polishing composition as described above between a polishing pad and a surface of the workpiece, and pressing the polishing pad and the surface of the workpiece together with the polishing composition disposed therebetween while the polishing pad and the surface of the workpiece are moving relative to each other to remove polysilicon from the surface of the workpiece at a rate that is greater than 1000 Å/min and at least five times greater than the rate at which the one or more selected from the group consisting of silicon dioxide, silicate glasses and silicon nitride are removed from the surface of the workpiece.

The following example is intended only to illustrate the invention and should not be construed as imposing limitations upon the claims.

### EXAMPLE

CMP Compositions A, B, C and D were prepared as shown in weight percent in Table 1 below:

TABLE 1

| | A | B | C | D |
|---|---|---|---|---|
| CeO₂ | 2.0% | 2.0% | 2.0% | 2.0% |
| PEI | none | 0.01% | 0.03% | 0.05% |
| DI-H₂O | 98.0% | 97.99% | 97.97% | 97.95% |

The “CeO₂” used in each CMP Composition was a calcined cerium oxide derived from a cerium carbonate precursor that had a Dmean secondary particle size of 140 nm. The PEI used in CMP Compositions B, C and D had a weight average molecular weight of 25,000 g/mol. A quantity of HNO₃ was added to CMP Compositions B, C and D sufficient to adjust the pH to 4.75. CMP Composition A, which did not contain any PEI, was a control and had a pH of 4.0.

CMP Compositions A, B, C and D were separately used to polish polysilicon, thermally grown silicon dioxide, borophosphosilicate glass and silicon nitride wafers. The polisher used in each case was an Applied Materials Mirra system. For all test runs, the polishing conditions were 3.0 psi membrane pressure, 3.5 psi retaining ring pressure, 3.0 psi inner tube pressure, 93 rpm head speed and 87 rpm table speed. The flow rate of the CMP Compositions was 150 ml/min. in each case. The polishing pad used in each case was a Rohm & Haas k-grooved IC1000 pad, with a Suba 4 backing. The polishing rate of each material in Å/min is set forth in Table 2 below, where “N/T” means “not tested”:

TABLE 2

| | A | B | C | D |
|---|---|---|---|---|
| POLY | 972 | 2165 | 1884 | 1898 |
| BPSG | N/T | 1369 | 195 | 153 |
| TOX | 1919 | 8 | 8 | 8 |
| NITRIDE | 983 | 111 | 118 | 124 |

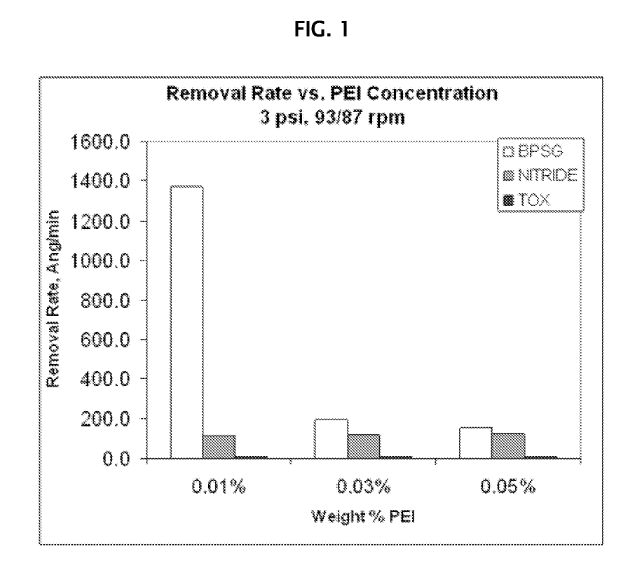

FIG. 1 is a graph showing the removal rate of borophosphosilicate glass (“BPSG”), silicon nitride (“NITRIDE”) and thermally grown silicon dioxide (“TOX”) as a function of PEI concentration for CMP Compositions B (0.01 wt % PEI), C (0.03 wt % PEI) and D (0.05 wt % PEI). FIG. 1 shows that less PEI is required to suppress the rate of thermally grown silicon dioxide and silicon nitride removal as compared to borophosphosilicate glass. It will be appreciated that the PEI concentration in CMP compositions according to the invention can be adjusted to suppress the removal rate of borophosphosilicate glass, as desired (e.g., to below 100 Å/min).

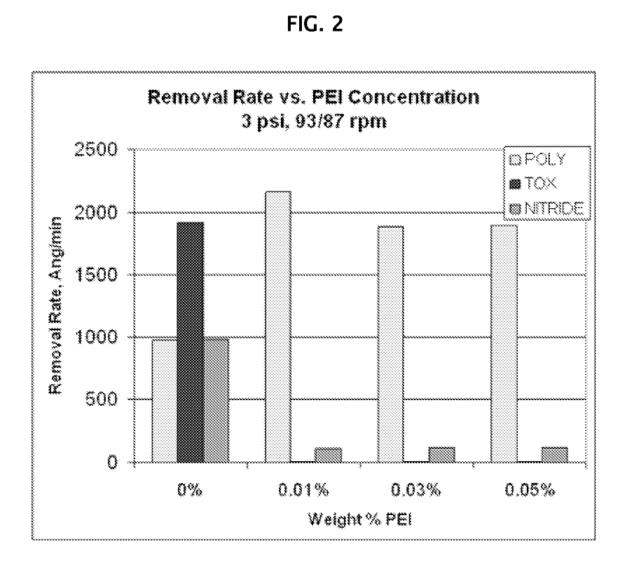

FIG. 2 is a graph showing the removal rate of polysilicon (“POLY”), silicon nitride (“NITRIDE”) and thermally grown silicon dioxide (“TOX”) as a function of PEI concentration for CMP Compositions A (0.0 wt % PEI), B (0.01 wt % PEI), C (0.03 wt % PEI) and D (0.05 wt % PEI). FIG. 2 shows that in the absence of PEI (CMP Composition A), thermally grown silicon dioxide and silicon nitride removal rates are high (˜1900 Å/min and ˜1000 Å/min, respectively). It can also be observed that in the absence of PEI, the removal rate for polysilicon is approximately 50% lower than the removal rate when the CMP Compositions contain any PEI concentration of greater than or equal to 0.01%. Thus, the presence of PEI in CMP Compositions B, C and D suppresses the removal rate of borophosphosilicate glass, silicon nitride and thermally grown silicon dioxide while increasing the removal rate of polysilicon.

Additional advantages and modifications will readily occur to those skilled in the art. Therefore, the invention in its broader aspects is not limited to the specific details and illustrative examples shown and described herein. Accordingly, various modifications may be made without departing from the spirit or scope of the general inventive concept as defined by the appended claims and their equivalents.

What is claimed is:

1. A method for preferentially removing polysilicon from a workpiece that includes polysilicon and one or more selected from the group consisting of silicon dioxide, silicate glasses and silicon nitride, the method comprising:
providing a polishing composition between a polishing pad and a surface of the workpiece, the polishing composition comprising water,
abrasive particles selected from the group consisting of ceria, copper oxide, iron oxide, nickel oxide, manganese oxide, silicon carbide, silicon nitride, tin oxide, titania, titanium carbide, tungsten oxide, yttria, zirconia and combinations thereof,
from about 0.005 to about 0.15% by weight of one or more polyalkyl amine compounds having a charge density greater than 7 meq/gram at a pH of 4.5, and
an amount of a pH adjusting material sufficient to adjust the pH of the polishing composition within the range of from about 3.5 to about 7; and
pressing the polishing pad and the surface of the workpiece together with the polishing composition disposed therebetween while the polishing pad and the surface of the workpiece are moving relative to each other to remove polysilicon from the surface of the workpiece at a rate that is greater than 1000 Å/min and at least five times greater than the rate at which the one or more selected from the group consisting of silicon dioxide, silicate glasses and silicon nitride are removed from the surface of the workpiece.

2. The method according to claim 1 wherein the abrasive particles consist of ceria having a mean diameter within the range of from about 100 nm to less than 150 nm.

3. The method according to claim 2 wherein the ceria abrasive particles are present in the polishing composition in an amount by weight of from about 0.5% to about 4%.

4. The method according to claim 1 wherein the polyalkyl amine is selected from the group consisting of polyethyleneimine, homopolymers and copolymers of polyvinylamine, polyaniline, polyvinylaniline, polyvinylpyridine and combinations thereof.

5. The method according to claim 1 wherein the polyalkyl amine is polyethyleneimine.

6. The method according to claim 5 wherein the polyethyleneimine has a molecular weight between about 2,000 g/mole and 70,000 g/mol.

7. The method according to claim 1 wherein the pH adjusting material is nitric acid.

8. The method according to claim 1 wherein:
the abrasive particles consist of ceria having a mean diameter within the range of from about 100 nm to less than 150 nm;
the abrasive particles are present in the polishing composition in an amount by weight of from about 0.5% to about 4%; and
the polyalkyl amine is polyethyleneimine having a molecular weight between about 2,000 g/mole and 70,000 g/mol.

9. The method according to claim 1 wherein abrasive particles in the polishing composition are initially bonded to the polishing pad but become dissociated from the polishing pad and dispersed in the water during the pressing step.

10. A method for preferentially removing polysilicon from a workpiece that includes polysilicon and one or more selected from the group consisting of silicon dioxide, silicate glasses and silicon nitride, the method comprising:
providing a polishing composition between a polishing pad and a surface of the workpiece, the polishing composition consisting essentially of water,
from about 1.5% to about 2.5% by weight of ceria having a mean diameter within the range of from about 100 nm to about 150 nm,
from about 0.01 to about 0.1% by weight of polyethyleneimine having a molecular weight of from about 2,000 g/mol to about 70,000 g/mol, and
an amount of nitric acid sufficient to adjust the pH of the polishing composition within the range of from about 4.7 to about 5.1; and
pressing the polishing pad and the surface of the workpiece together with the polishing composition disposed therebetween while the polishing pad and the surface of the workpiece are moving relative to each other to remove polysilicon from the surface of the workpiece at a rate that is at least five times greater than the rate at which the one or more selected from the group consisting of silicon dioxide, silicate glasses and silicon nitride are removed from the surface of the workpiece.

11. A chemical-mechanical polishing composition for preferentially removing polysilicon from a workpiece that includes polysilicon and one or more selected from the group consisting of silicon dioxide, silicate glasses and silicon nitride, the polishing composition comprising:
water;
abrasive particles selected from the group consisting of ceria, copper oxide, iron oxide, nickel oxide, manganese oxide, silicon carbide, silicon nitride, tin oxide, titania, titanium carbide, tungsten oxide, yttria, zirconia and combinations thereof;
from about 0.005 to about 0.15% by weight of one or more polyalkyl amine compounds having a charge density greater than 7 meq/gram at a pH of 4.5; and
an amount of a pH adjusting material sufficient to adjust the pH of the polishing composition within the range of from about 3.5 to about 7.

12. The polishing composition according to claim 11 wherein the abrasive particles consist of ceria having a mean diameter within the range of from about 100 nm to less than 150 nm.

13. The polishing composition according to claim 12 wherein the ceria abrasive particles are present in the polishing composition in an amount by weight of from about 0.5% to about 4%.

14. The polishing composition according to claim 11 wherein the polyalkyl amine is selected from the group consisting of polyethyleneimine, homopolymers and copolymers of polyvinylamine, polyaniline, polyvinylaniline, polyvinylpyridine and combinations thereof.

15. The polishing composition according to claim 11 wherein the polyalkyl amine is polyethyleneimine.

16. The polishing composition according to claim 15 wherein the polyethyleneimine has a molecular weight between about 2,000 g/mole and 70,000 g/mol.

17. The polishing composition according to claim 11 wherein the pH adjusting material is nitric acid.

18. The polishing composition according to claim 11 wherein:
the abrasive particles consist of ceria having a mean diameter within the range of from about 100 nm to less than 150 nm;
the abrasive particles are present in the polishing composition in an amount by weight of from about 0.5% to about 4%; and
the polyalkyl amine is polyethyleneimine having a molecular weight between about 2,000 g/mole and 70,000 g/mol.

19. The polishing composition according to claim 11 wherein the polishing composition is formed in situ during polishing by dissociating the abrasive particles from a polishing pad.

20. The polishing composition according to claim 11 wherein the polishing composition consists essentially of:
water,
from about 1.5% to about 2.5% by weight of ceria having a mean diameter within the range of from about 100 nm to about 150 nm;
from about 0.01 to about 0.1% by weight of polyethyleneimine having a molecular weight of from about 2,000 g/mol to about 70,000 g/mol; and
an amount of nitric acid sufficient to adjust the pH of the polishing composition within the range of from about 4.7 to about 5.1.
